(19) United States
(12) Patent Application Publication
(10) Pub. No.: US 2005/0254569 A1
(43) Pub. Date: Nov. 17, 2005

(54) System and method for generating equalization coefficients

(76) Inventor: Afshin Momtaz, Laguna Hills, CA (US)

Correspondence Address: CHRISTIE, PARKER & HALE, LLP, PO BOX 7068, PASADENA, CA, 91109-7068, US

(21) Appl. No.: 10/846,316

(22) Filed: May 14, 2004

(51) Int. Cl. H03K 5/159

(52) U.S. Cl. 375/233; 375/232

(57) ABSTRACT

A least mean square (“LMS”) circuit generates equalization coefficients using demultiplexed data signals. Serial equalized data output by a decision feedback equalizer is demultiplexed into two or more parallel signals. The LMS clock signal is phase aligned with a retimer clock signal and demultiplexer clock signal to provide data to the LMS circuit in a desired sequence.

### TECHNICAL FIELD

This application relates to data communications and, more specifically, to a system and method for generating equalization coefficients.

### BACKGROUND

In a typical data communications system data is sent from a transmitter to a receiver over a communications media such as a wire or fiber optic cable. In general, the data is encoded in a manner that facilitates effective transmission over the media. For example, data may be encoded as a sequence of binary symbols that are transmitted through the media as a signal stream.

In many applications symbols in a signal stream are corrupted as they pass through the media. For example, bandwidth limitations inherent in the media tend to create increasing levels of data distortion in a received signal. In particular, band-limited channels tend to spread transmitted pulses. If the width of the spread pulse exceeds a symbol duration, overlap with neighboring pulses may occur, degrading the performance of the receiver. This phenomenon is called inter-symbol interference (“ISI”). In general, as the data rate or the distance between the transmitter and receiver increases, the bandwidth limitations of the media tend to cause more inter-symbol interference.

To compensate for such problems in received signals, conventional high speed receivers may include filters and equalizers that may, for example, cancel some of the effects inter-symbol interference or other distortion. Moreover, some applications use adaptive filters or equalizers that automatically adjust their characteristics in response to changes in the characteristics of the communications media. Typically, the adaptation process involves generating coefficients that control the characteristics of the filter or equalizer. To this end, a variety of algorithms have been developed for generating these coefficients.

The least mean square (“LMS”) algorithm is commonly used for optimizing coefficients for various applications such as a finite impulse response (“FIR”) filter and an adaptive equalizer such as decision feedback equalizers (“DFE”). In general, an LMS algorithm generates adaptive coefficients by modifying the current coefficients based on an algorithm applied to received data and error signals.

A conventional two tap decision feedback equalizer 100 is depicted in FIG. 1. A summer 104 combines incoming data 102 with two feedback signals 106 and 108. A slicer 110 converts the output of the summer (soft decision) to a binary signal. A retimer that includes two flip flops 112 and 118 recovers data from the binary signal in response to a recovered clock signal 114. Each flip flop 112 and 118 generates a retimed data signal 116 and 120, respectively.

The retimed data signals 116 and 120 are fed back to the summer 104 via a pair of multipliers 122 and 124 that multiply the signals 116 and 120 by equalization coefficients g1 and g2, respectively. The equalization coefficients are typically negative numbers. The outputs of the multipliers 122 and 124 provide scaled feedback signals 106 and 108 that are then combined with incoming data 102 as discussed above. The decision feedback equalizer therefore serves to subtract two previous symbols (n−1) and (n−2) from a current symbol (n) to reduce or eliminate channel induced distortion such as inter-symbol interference. In this circuit, the output 120 of the second flip flop 118 provides the recovered and equalized data.

For the two tap DFE of FIG. 1 the LMS algorithm may be described by the following equations:
g1(n)=g1(n−1)+μ*e*y1 EQUATION 1
g2(n)=g2(n−1)+μ*e*y2 EQUATION 2
where g(n−1) represents the coefficient immediately preceding coefficient (n), μ is a scalar that relates to, for example, the gain of the feedback loop and the speed with which the loop converges, e is an error signal, and y1 and y2 are hard decision signals output by the first flip flop 112 and the second flip flop 120, respectively.

In high speed applications such as 10 Gigabit (“Gbit”) receivers, the design of the LMS circuit may present several challenges. For example, it may be difficult to design and implement a reliable yet cost effective circuit for such applications. Moreover, the resulting circuit may consume a relatively large amount of power and space on an integrated circuit die and may be subject to unacceptable delays in the high speed data path.

As an example, from FIG. 1 it may be observed that the 10 Gbit signals y1 and y2 are inputs to the LMS algorithm. This additional loading on the 10 Gbit signals presents several problems. For example, the additional loading may adversely increase the delay through the feedback paths. At high speeds such additional delay may be unacceptable. In addition, the logic circuits (e.g., flip flops) that provide these signals to an LMS circuit must be capable of receiving a 10 Gbit signal. Typically, such logic circuits consume a relatively large amount of power and space on the die of the receiver integrated circuit.

Accordingly, a need exists for improved techniques for generating equalization coefficients particularly in high speed applications.

### SUMMARY

The invention relates to a system and method for generating equalization coefficients. For convenience, an embodiment of a system or method constructed according to the invention will be referred to herein simply as an “embodiment.”

In some embodiments, an LMS circuit generates equalization coefficients using demultiplexed data signals. For example, the serial equalized data output by a decision feedback equalizer is demultiplexed into two or more parallel signals. In embodiments that use such a demultiplexer to process received data at lower speeds, data may be provided to the LMS circuit without imparting additional loading on the high speed (e.g., 10 Gbit) data signals.

In some embodiments, the LMS circuit is clocked by a clock signal that is phase adjusted to correlate to a high speed clock signal used to retime the received data and a lower speed clock signal used to demultiplex the data. For example, the LMS clock may be phase aligned with the retimer clock and the transition edges of the LMS clock may be correlated to coincide with a given phase level of the demultiplexer clock.

In some embodiments, a delay lock loop provides synchronization between the demultiplexed data signals, an error signal and the LMS clock to enable the LMS circuit to clock in appropriate temporal states of the received signal. For example, the delay lock loop generates the LMS clock in phase lock with the retimer clock and adjusts the phase of the LMS clock according to the value of a sample of the demultiplexer clock.

### BRIEF DESCRIPTION OF THE DRAWINGS

These and other features, aspects and advantages of the present invention will be more fully understood when considered with respect to the following detailed description, appended claims and accompanying drawings, wherein:

FIG. 1 is a simplified block diagram of one embodiment of a two tap decision feedback equalizer;

FIG. 2 is a simplified block diagram of one embodiment of a two tap decision feedback equalizer and least mean square circuit;

FIG. 3 is a simplified diagram of one embodiment of signal timing in the decision feedback equalizer of FIG. 2;

FIG. 4 is a simplified block diagram of one embodiment of a two tap decision feedback equalizer and least mean square circuit constructed in accordance with the invention;

FIG. 5 is a simplified diagram of one embodiment of signal timing in the decision feedback equalizer of FIG. 4;

FIG. 6 is a simplified flowchart of one embodiment of equalization operations that may be performed in accordance with the invention;

FIG. 7 is a simplified block diagram of one embodiment of a delay lock loop constructed in accordance with the invention;

FIG. 8 is a simplified flowchart of one embodiment of delay lock loop operations that may be performed in accordance with the invention;

FIG. 9 is a simplified diagram of one embodiment of signal timing in the delay lock loop of FIG. 7;

FIG. 10 is a simplified diagram of one embodiment of signal timing in the delay lock loop of FIG. 7;

FIG. 11 is a simplified block diagram of one embodiment of a delay lock loop constructed in accordance with the invention; and

FIG. 12 is a simplified block diagram of one embodiment of an optical communication system constructed in accordance with the invention.

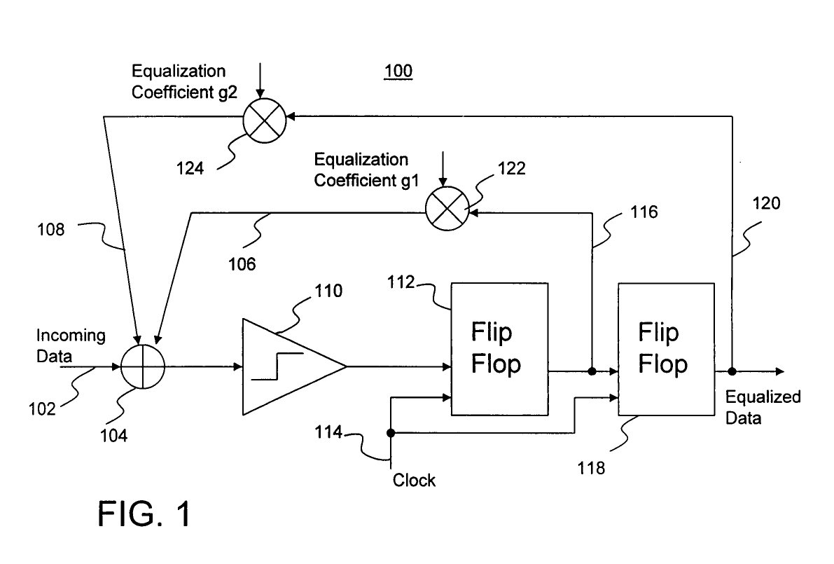

In accordance with common practice the various features illustrated in the drawings may not be drawn to scale. Accordingly, the dimensions of the various features may be arbitrarily expanded or reduced for clarity. In addition, some of the drawings may be simplified for clarity. Thus, the drawings may not depict all of the components of a given apparatus or method. Finally, like reference numerals denote like features throughout the specification and figures.

### DETAILED DESCRIPTION

The invention is described below, with reference to detailed illustrative embodiments. It will be apparent that the invention may be embodied in a wide variety of forms, some of which may be quite different from those of the disclosed embodiments. Consequently, the specific structural and functional details disclosed herein are merely representative and do not limit the scope of the invention.

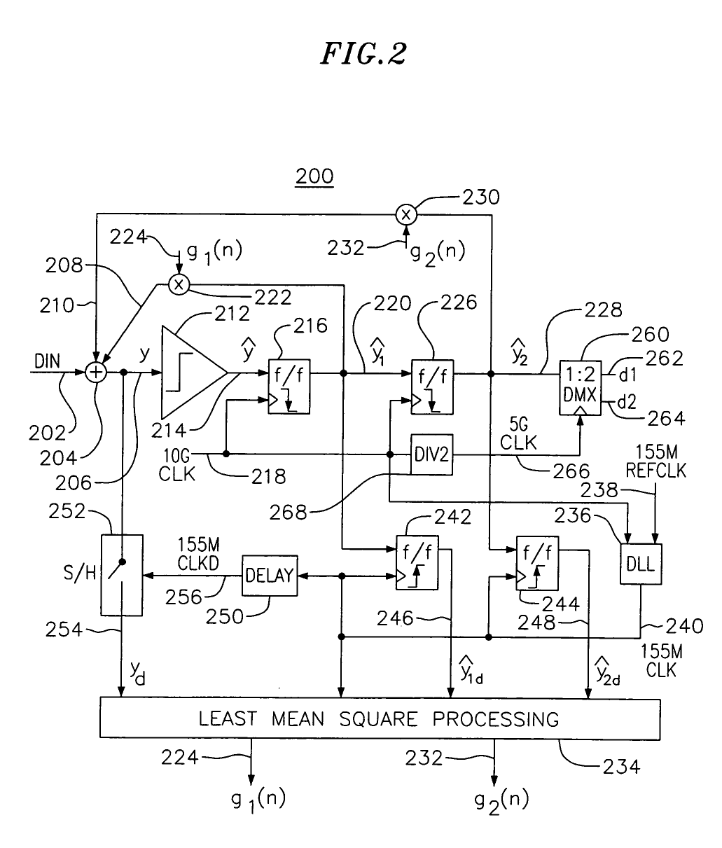

FIG. 2 is a simplified block diagram of a two tap decision feedback equalizer (“DFE”) and a least mean square (“LMS”) circuit 200 where the LMS circuit is implemented using conventional techniques. In the DFE a summer 204 combines incoming data 202 with two feedback signals 208 and 210 to generate a summed signal y 206 (soft decision). A slicer 212 converts the signal 206 to a binary signal ŷ 214. A retimer that includes two flip flops 216 and 226 recovers data from the binary signal in response to a recovered 10 GHz clock signal 10GCLK 218. Each flip flop 216 and 226 generates a retimed data signal ŷ₁ 220 and ŷ₂ 228, respectively.

The data signals 220 and 228 are fed to pair of multipliers 222 and 230 that multiply the signals 220 and 228 by equalization coefficients g₁(n) 224 and g₂(n) 232, respectively. The outputs of the multipliers 222 and 230 provide scaled feedback signals 208 and 210 that are combined with the incoming data 202 as discussed above.

The LMS circuit includes an LMS processing component 234 that generates the equalization coefficient signals g₁(n) and g₂(n) and associated clock and sampling circuitry. Typically, the LMS algorithm is implemented in the digital domain and runs at a lower clock speed than the DFE. For example, the clock for the LMS circuit may be a subsampled version of the DFE clock. In FIG. 2, a delay lock loop (“DLL”) 236 generates a 155 MHz clock 155MCLK 240 for the LMS circuit by phase aligning a 155 MHz reference clock signal 155MREFCLK 238 with the 10GCLK signal.

The three data input signals for the LMS algorithm (e.g., Equations 1 and 2) are sampled at the 155 MHz rate before being fed to the LMS processing component 234. In FIG. 2 the error signal is derived from the soft decision signal y and the hard decision signals are provided by signals ŷ₁ and ŷ₂.

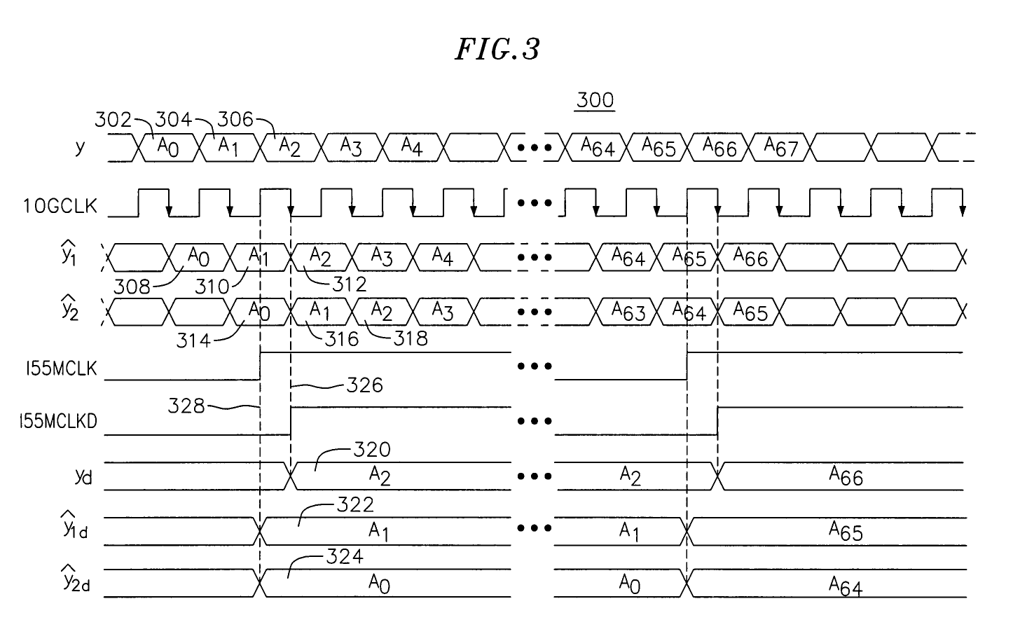

Since these signals are time aligned with the 10GCLK signal, the LMS clock and sampling circuitry aligns the 155MCLK domain with the data from the 10GCLK domain. Here, a pair of flip flops 242 and 244 latch the signals ŷ₁ and ŷ₂ to provide signals ŷ_{1d} and ŷ_{2d}, respectively, at the 155 MHz rate. In addition a sample and hold circuit 252 samples the signal y to provide ŷ_{d} at the 155 MHz rate. In this case an analog delay circuit 250 delays the signal 155MCLK to provide a delayed clock signal 155MCLKD 256 to the sample and hold circuit 252. The above timing relationships are described in more detail by the timing diagram depicted in FIG. 3.

FIG. 3 is a simplified timing diagram 300 that illustrates how the three signals y, ŷ₁ and ŷ₂ from the 10GCLK domain are provided to the LMS processing component in the 155MCLK domain. Three consecutive soft decision data symbols are represented as A0 302, A1 304 and A2 306. It should be appreciated that after retiming, the symbols A0, A1 and A2 will correspond to y2, y1 and e, respectively, in Equations 1 and 2. To generate the error signal e, the LMS circuit 234 may subtract the signal A2 from either +1 or −1 (depending on the polarity of A2). The flip flops 216 and 226 are clocked on the falling edge of the 10GCLK signal. Accordingly, the timing diagrams show when A0, A1 and A2 appear on ŷ₁ as A0 308, A1 310 and A2 312 and on ŷ₂ as A0 314, A1 316 and A2 318.

The 155MCLK signal is phase aligned with the rising edge of the 10GCLK signal as represented by dashed line 328. Accordingly, ŷ₁ and ŷ₂ may be sampled on the rising edge of the 155MCLK signal to provide A1 322 to ŷ_{1d} and A0 324 to ŷ_{2d}.

The 155MCLKD signal is approximately phase aligned with the falling edge of the 10GCLK signal as represented by dashed line 326. Accordingly, y may be sampled on the rising edge of the 155MCLKD signal to provide A2 320 to y_{d}.

The LMS component 470 may then clock in y_{d}, ŷ_{1d} and ŷ_{2d} on, for example, the falling edge of the 155MCLK signal.

In FIG. 2, the two sub-sampling flip flops 242 and 244 are connected to ŷ₁ and ŷ₂. As a result they increase the load on the critical 10 Gbit DFE data path. This additional load may increase the size and power consumption of the DFE. Moreover, this additional load may limit the functionality of the DFE by increasing the DFE loop path delay beyond the allowable limit. Furthermore, the analog delay circuit 250 has a delay of approximately 50 pS. As a result, this circuit may consume a relatively large amount of power.

FIG. 2 illustrates that in some applications, a demultiplexer (“DMX”) 260 may be used to convert the 10 Gbit serial output signal ŷ₂ to slower, parallel signals. In this case, the demultiplexer 260 generates two parallel signals d₁ 262 and d₂ 264 using a 5 GHz clock signal 5GCLK 266. The 5GCLK signal is generated by a divider (“DIV2”) 268 that divides the 10GCLK signal by two.

In DFEs that use such a demultiplexer, an improved DFE may be realized by using demultiplexed data to provide the y1 and y2 signals for the LMS algorithm. In this case, additional loading on the 10 GHz signals by the LMS circuit may be avoided.

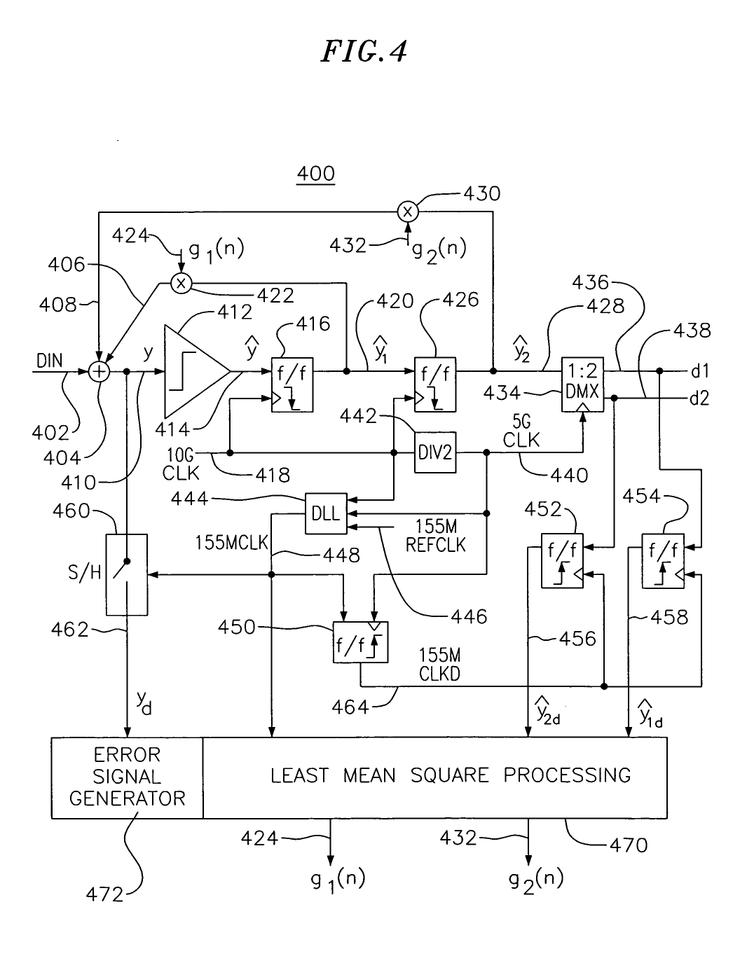

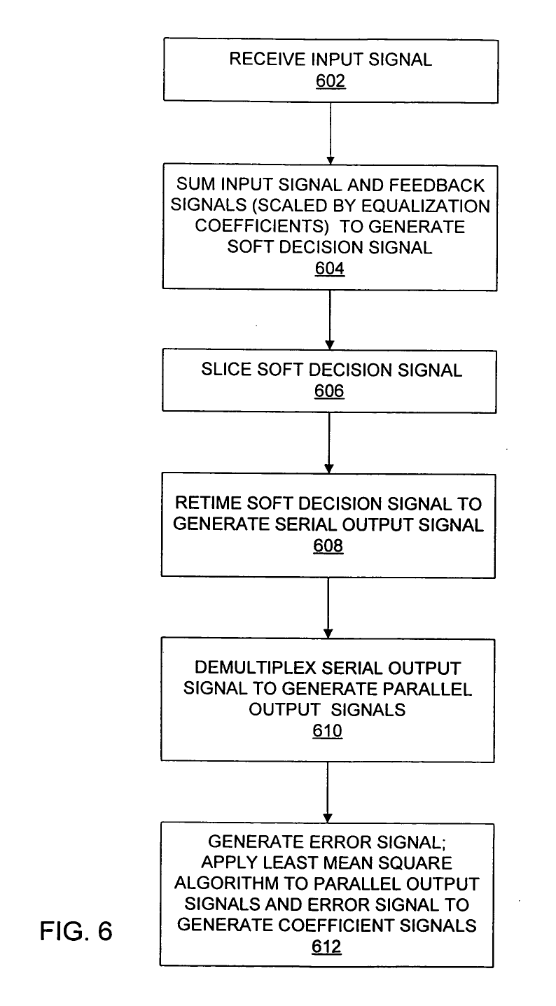

Referring to FIG. 4, one embodiment of a two tap decision feedback equalizer (“DFE”) and a least mean square (“LMS”) circuit 400 constructed according to the invention is described. The operation of the circuit will be described in conjunction with flowchart of FIG. 6.

As represented by block 602, an input data signal 402 is provided to a summer 404. The summer 404 combines the incoming data 402 with feedback signals 406 and 408 to generate signal y 410 (block 604). As discussed herein the feedback signals 406 and 408 are scaled by adaptive equalization coefficients. As represented by blocks 606 and 608, a slicer 412 generates a signal ŷ 414 that is retimed by flip flops 416 and 426 to generate ŷ₁ 420 and ŷ₂ 428, respectively. Multipliers 422 and 430 multiply signals 420 and 428 by equalization coefficients g₁(n) 424 and g₂(n) 432 to provide signals 406 and 408, respectively, as discussed above in conjunction with block 604.

As represented by block 610, a demultiplexer (“DMX”) 434 demultiplexes the 10 Gbit serial output signal ŷ₂ to two parallel signals d₁ 436 and d₂ 438 using a 5 GHz clock signal 5GCLK 440. The 5GCLK signal is generated by a divider 442 that divides a 10 GHz retimer clock signal 10GCLK 418 by two. Accordingly, the demultiplexer 434 generates the signals d₁ and d₂ at a rate of 5 Gbits.

As represented by block 612, a clock generator and latching circuit generates clock signals to latch the signals y, d₁ and d₂ to provide the signals y_{d} 462, ŷ_{1d} 458 and ŷ_{2d} 456, respectively, to an LMS processing component 470 which then generates the equalization coefficients g₁(n) and g₂(n). Here, a pair of flip flops 454 and 452 sample the signals d₁ and d₂ to generate the signals ŷ_{1d} and ŷ_{2d}. In addition, a sample and hold circuit 460 samples y to generate y_{d}. An error signal generator 472 may generate the error signal e by, for example, subtracting the signal A2 from either +1 or −1 (depending on the polarity of A2). Depending on the implementation, the error signal generator 472 may be or may not be incorporated into the LMS circuit 470.

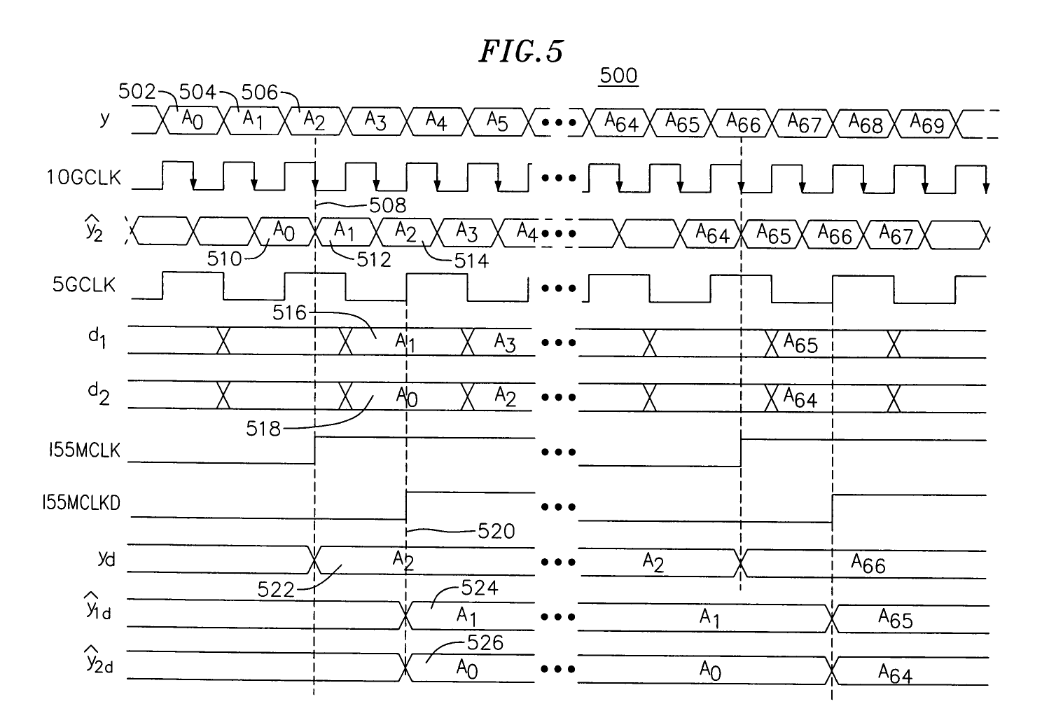

To provide the y_{d}, ŷ_{1d} and ŷ_{2d} signals to the LMS component 470 at the appropriate time, the flip flops 454, 452 and the sample and hold circuit are clocked by two 155 MHz clock signals 155MLKC 448 and 155MCLKD 464. A clock generator including a delay lock loop 444 and associated flip flop 450 generates the 155MLKC and 155MCLKD signals. The delay lock loop 444 generates the 155MCLK signal so that it is phase aligned with the 10GCLK signal. For example, the edges of the 155MCLK signal are aligned with a falling edge of the 10GCLK signal. In addition, the delay lock loop 444 aligns the rising edge of the 155MCLK signal with the “high” phase of the 5GCLK signal. The flip flop 450 delays the 155MCLK signal to provide a delayed clock signal 155MCLKD to the flip flops 454 and 452. The above timing relationships are described in more detail by the timing diagram depicted in FIG. 5.

FIG. 5 is a simplified timing diagram 500 that illustrates how the three signals y, ŷ₁ and ŷ₂ from the 10GCLK domain are provided to the LMS processing component 470 in the 155MCLK domain. Three consecutive soft decision data symbols are represented as A0 502, A1 504 and A2 506. After retiming and processing of A2 as discussed above, the symbols A0, A1 and A2 will correspond to y2, y1 and e, respectively, in Equations 1 and 2. The flip flop 426 is clocked on the falling edge of the 10GCLK signal. Accordingly, the timing diagram illustrates the time at which A0, A1 and A2 appear on ŷ₂ as A0 510, A1 512 and A2 514.

The multiplexer 434 outputs d₁ and d₂ on the falling edge of the 5GCLK signal. Thus, the timing diagram illustrates the time at which A1 and A2 appear on d₁ and d₂ as A1 516 and A2 518, respectively.

The delay lock loop 444 aligns the edges of the 155MCLK signal with the rising edge of the 10GCLK signal as represented by dashed line 508. Accordingly, y₂ is sampled on the rising edge of the 155MCLK signal to provide A2 522 to y_{d}.

The flip flop 450 aligns the edges of the 155MCLKD signal with the rising edge of the 5GCLK signal as represented by dashed line 520. Accordingly, d1 and d2 are sampled on the rising edge of the 155MCLKD signal to provide A1 524 and A2 526 to ŷ_{1d} and ŷ_{2d}, respectively.

The LMS component 470 may then clock in y_{d}, ŷ_{1d} and ŷ_{2d} on, for example, the falling edge of the 155MCLK signal. After processing this data in accordance with, for example, Equations 1 and 2, the LMS component 470 provides the updated equalization coefficients g₁(n) and g₂(n) to the multipliers 422 and 430, respectively.

The embodiment of FIG. 4 may provide an advantage over conventional DFEs by eliminating additional loads on the high speed data path signals. Moreover, this embodiment may be implemented using fewer very high speed components (e.g., flip flops). As a result, the DFE may consume less power and occupy less area in the receiver. In addition, by eliminating an analog delay circuit, additional reductions in power consumption may be achieved.

To achieve the desired timing between the 10 GHz, 5 GHz and 155 MHz clock domains, the delay lock loop and associated clock circuitry aligns the 155 MHz clock with respect to both the 10 GHz clock and the 5 GHz clock. Even though the 5 GHz clock is derived from the 10 GHz clock, the phase of the 5 GHz clock is still taken into account to ensure that the desired data signals are available to the flip flops 454 and 452 and the sample and hold circuit 460 at the appropriate times. To this end, the delay lock loop is configured to ensure the timing relationship diagrammed in FIG. 5.

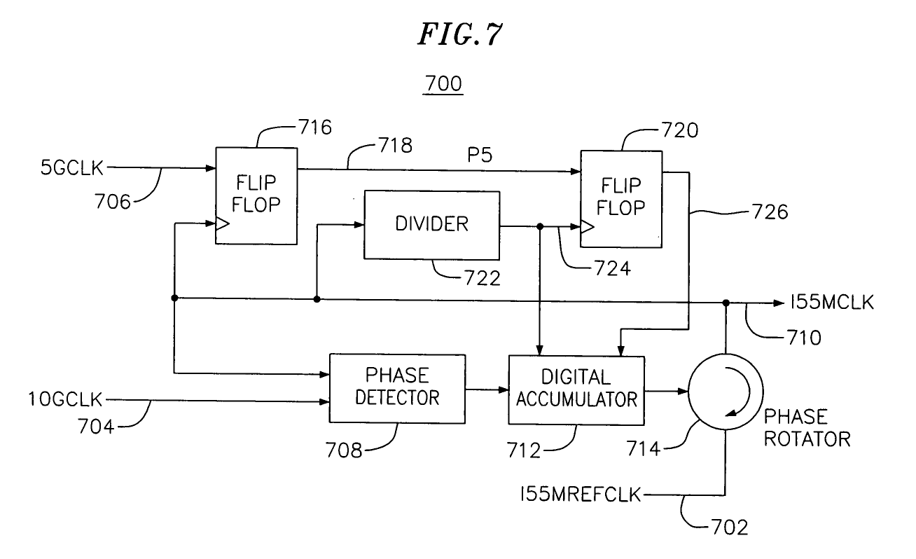

FIG. 7 depicts one embodiment of a delay lock loop 700 that may be used in the circuit 400. A phase detector 708 generates an early/late signal depending on the phase relationship of a 155 MHz clock signal 155MCLK 710 and a 10 GHz clock signal 10GCLK 704. A digital accumulator 712 filters the early/late signal to provide a digital code signal to a phase rotator 714. Based on this digital code signal, the phase rotator 714 adjusts a 155 MHz reference clock signal 155MREFCLK 702 to align the rising edge of the 155MCLK signal with the falling edge of the 10GCLK signal.

To adjust the phase of the 155MCLK signal according to a 5 GHz signal 5GCLK 706, the digital accumulator is configured to delay the 155MCLK signal by, for example, 100 pS. A flip flop 716 samples the 5GCLK signal using the 155MCLK signal. The output P5 718 of the flip flop 716 indicates whether the relationship of the 5GCLK and 155MCLK signals is correct.

An example of when the timing relationship is not correct is depicted in the timing diagram 900 of FIG. 9. Dashed line 902 represents that the low phase of the 5GCLK signal is sampled at the rising edge of the 155MCLK signal and, as a result, the P5 signal is set to a low state. In this case, the digital code output by the digital accumulator 712 is increased by an amount that will cause the phase rotator 714 to delay the 155MCLK signal by 100 pS.

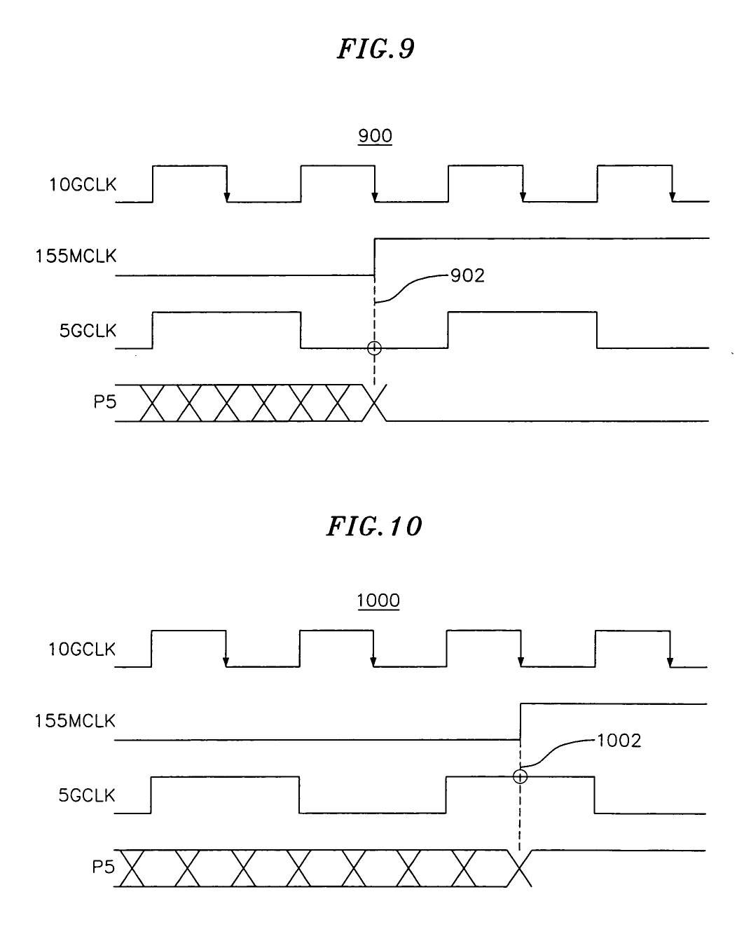

After the phase of the 155MCLK signal is adjusted, the timing relationship will be as depicted in the timing diagram 1000 of FIG. 10. Dashed line 1002 represents that the high phase of the 5GCLK signal is sampled at the rising edge of the 155MCLK signal and, as a result, the P5 signal is set to a high state. Here, since the P5 signal indicates that the timing relationship of the 5GCLK and 155MCLK signals is correct, the digital code is not changed. The timing diagrams 900 and 1000 also illustrate that the falling edge of the 10GCLK signal is aligned with the rising edge of the 155MCLK signal.

The flip flop 720 and a divider 722 that provides a reduced rate clock signal 724 are used to reduce the rate at which the P5 signal is provided to the digital accumulator 712. This may be used, for example, to ensure that the 155MCLK has changed as a result of a phase adjustment before another phase adjustment is initiated. Here, the digital accumulator uses the clock 724 to determine when to check the value of a reduced rate P5 signal 726. In one embodiment the divider 722 uses a divider value of 32 to generate a 9.7 MHz clock signal from the 155MCLK signal.

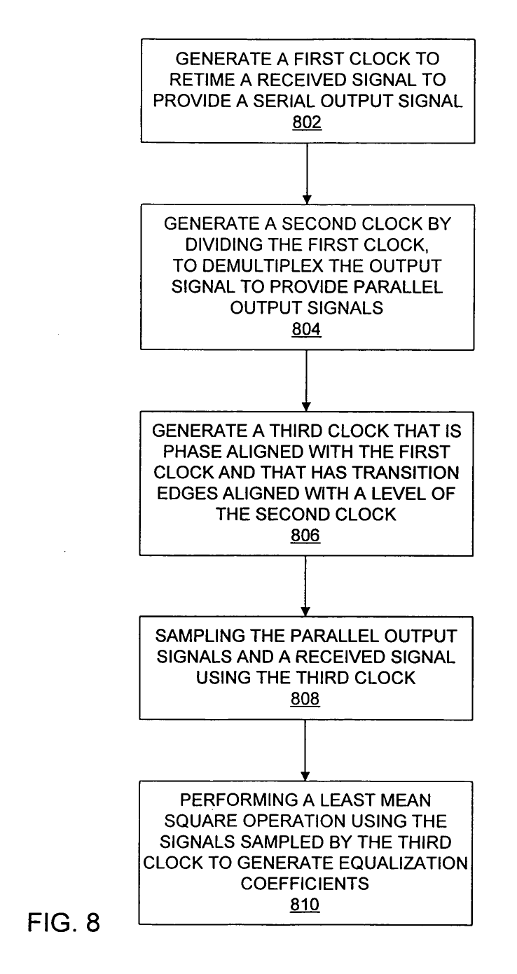

The operation of the delay lock loop in conjunction with the DFE and LMS circuit may be summarized as described in the flowchart of FIG. 8. As represented by block 802, a first clock signal (e.g., the 10GCLK signal) is generated to drive the DFE retimer flip flops (e.g., flip flops 416 and 426 in FIG. 4). As represented by block 804, the first clock signal is divided to generate a second clock signal (e.g., the 5GCLK signal) to drive a demultiplexer (e.g., demultiplexer 434). Next, a third clock signal (e.g., the 155MCLK signal) is generated with the appropriate phase relationships with the first and second clock signals (block 806). As represented by block 808, the output of the demultiplexer and a received signal (e.g., the soft decision signal that may be used to derive an error signal) are sampled using the third clock signal. Finally, the LMS operation is performed using the data sampled at block 808 (block 810).

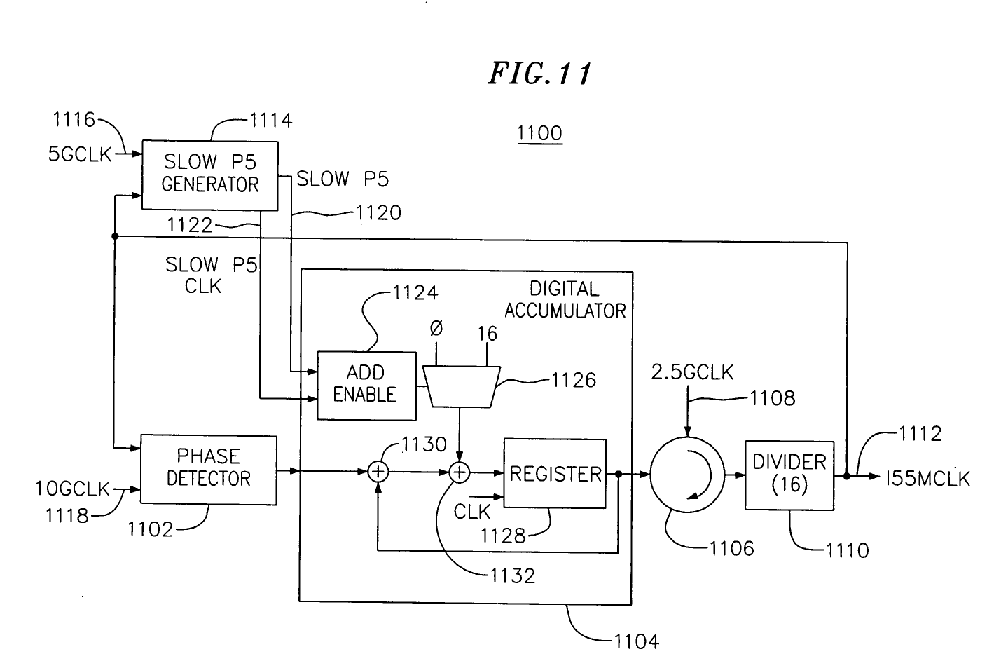

FIG. 11 depict one embodiment of a delay lock loop that generates a 155MCLK signal 1112 from a 2.5 GHz reference clock signal 1108. A phase detector 1102 generates an early/late signal depending on the phase relationship of the 155MCLK signal and a 10 GHz clock signal 10GCLK 1118. A digital accumulator 1104 filters the early/late signal to provide a digital code signal to a phase rotator 1106. Based on this digital code signal, the phase rotator 1106 adjusts the reference clock signal 1108 to produce a 2.5 GHz that is divided by a divider 1110 to generate the 155MCLK signal so that the rising edge of the 155MCLK signal is aligned with the falling edge of the 10GCLK signal.

A slow P5 generator 1114 generates a slow P5 signal 1120 and a slow P5 clock signal 1122 to adjust the phase of the 155MCLK signal according to a 5 GHz signal 5GCLK 1116 as discussed above. For example, when a transition (e.g., a falling edge) of the slow P5 clock occurs and the slow P5 signal is low, an add enable circuit may control, for example, a multiplexer 1126 to output a code of “16” for one cycle of an accumulator clock signal CLK. An adder 1132 then adds this code to the digital code being accumulated by the digital accumulator 1104. As a simplified example, the accumulation operation is represented by the register 1128 and an adder 1130 in FIG. 11. When the digital accumulator 1104 adds 16 to the digital code, in this example the phase rotator 1106 will then delay the 155MCLK signal by 100 pS.

When the next transition of the slow P5 clock occurs the digital accumulator 1104 will again check the state of the slow P5 signal. If the slow P5 signal is high, the output of the multiplexer will remain at the default of “0” so that the digital code of the digital accumulator 1104 remains unaffected.

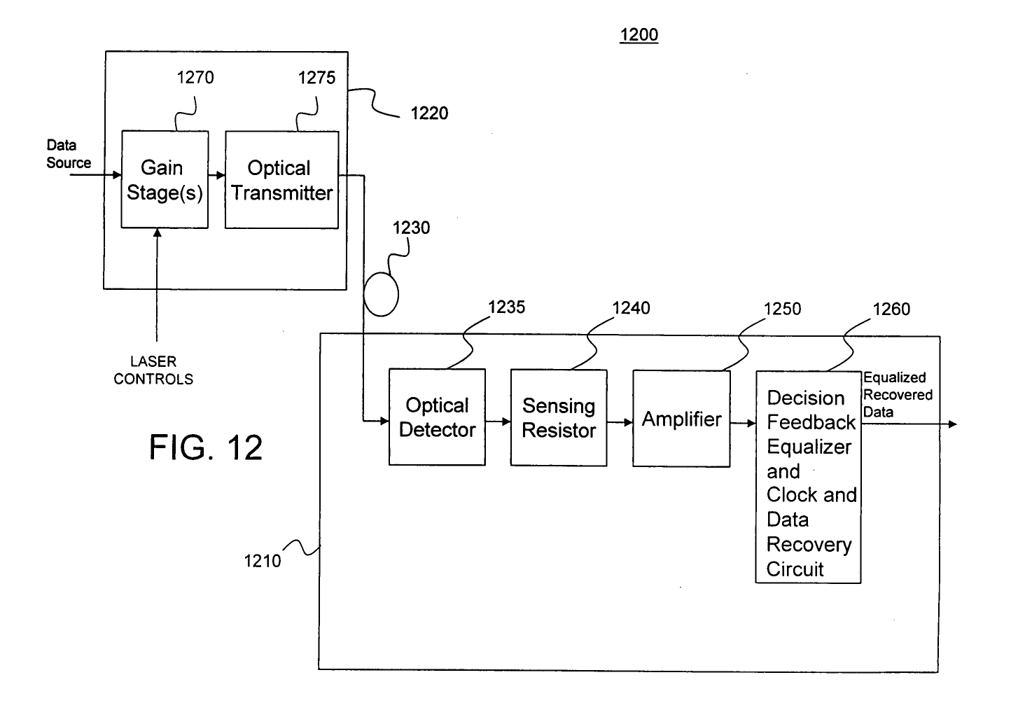

The least mean square techniques described herein may be integrated into any of a variety of applications. For example, referring to FIG. 12, the described least mean square circuit may be incorporated into an optical receiver assembly 1210 of an optical communication system 1200. The optical system 1200 includes an optical transmitter 1220 and an optical fiber network 1230 that carries the optical signal to the optical receiver assembly 1210. Those skilled in the art will appreciate that the teachings of the invention are not limited to a single optical transmitter and receiver or to optical receivers. For example, practical optical communications systems may have one or more optical transmitters as well as one or more optical receivers.

The illustrated receive path includes an optical detector 1235, sensing resistor 1240, one or more amplifier(s) 1250, and an integrated decision feedback equalizer and clock and data recovery circuit 1260. The optical detector 1235 may comprise a known prior art optical detector implementation. Such prior art detectors convert incoming optical signals into corresponding electrical output signals that may be electronically monitored.

A transmit path includes, by way of example, one or more gain stage(s) 1270 coupled to an optical transmitter 1275. The gain stage(s) 1270 may have multiple stages, and may receive one or more control signals for controlling various different parameters of the output of the optical transmitter. In one embodiment an analog data source provides an analog data signal that modulates the output of the optical transmitter. In other embodiments, baseband digital modulation or frequency modulation may be used.

In this embodiment, the gain stage(s) 1270 amplify the incoming data signal from the data source according to laser control signals. The amplified data signal, in turn, drives the optical transmitter 1275.

The optical transmitter may, for example, be a light emitting diode or a surface emitting laser or an edge emitting laser that operate at high speeds such as 10 Gigabits per second (“Gbps”) or higher. The optical transmitter 1275 thereby generates an optical data signal that provided to a fiber optic cable 1230.

The fiber optic cable 1230 carries the optical data signal to the optical detector 1235. In operation, when the transmit optical beam is incident on a light receiving surface area of the optical detector, electron-hole pairs are generated. A bias voltage applied across the optical detector 1235 generates a flow of electric current having an intensity proportional to the intensity of the incident light. In one embodiment, this current flows through sensing resistor 1240, and generates a voltage.

The sensed voltage is amplified by the one or more amplifier(s) 1250 and the output of amplifier(s) 1250 drives the integrated decision feedback equalizer and clock and data recovery circuit 1260. As illustrated in FIG. 4, the decision feedback equalizer may include, by way of example, a slicer that generates a binary signal that drives a clock and data recovery circuit. The clock and data recovery circuit generates an extracted clock signal from the binary signal that is then used to retime the equalized data as discussed above. One example of an integrated decision feedback equalizer and clock and data recovery circuit is described in U.S. patent application Ser. No. 10/823,252, filed Apr. 10, 2004, the disclosure of which is hereby incorporated by reference herein.

A receiver constructed according to the invention may support various data protocols and date rates. For example, in one embodiment the receiver is a multi-rate SONET/SDH/10GE/FEC receiver that may operate at very high speeds including, for example, 9.953, 10.3125, 10.664 or 10.709 Gbps. This receiver includes, in a single chip solution, an optical equalizer and CDR as discussed above, a linear amplifier, deserializer and other components.

In one embodiment the receiver chip is implemented using CMOS technology. However, the teachings herein are applicable to other types of processes including for example, GaAs, Bi-MOS, Bipolar, etc.

The teachings herein are applicable to a variety of applications and associated architectures. For example, equalization coefficients may be generated for a decision feedback equalizer having one or more taps. Two or more parallel demultiplexed signals may by used to provide data to the LMS circuit.

The clocks described herein may be generated by a variety of clock circuits including, for, example, divider circuits, delay lock loops and phase lock loops. For example, the 5 GHz clock described above may be generated using a phase lock loop.

Different embodiments of the invention may include a variety of hardware and software processing components. In some embodiments of the invention, hardware components such as controllers, state machines and/or logic are used in a system constructed in accordance with the invention. In some embodiment of the invention, code such as software or firmware executing on one or more processing devices may be used to implement one or more of the described operations.

Such components may be implemented on one or more integrated circuits. For example, in some embodiments several of these components may be combined within a single integrated circuit. In some embodiments some of the components may be implemented as a single integrated circuit. In some embodiments some components may be implemented as several integrated circuits.

The components and functions described herein may be connected/coupled in many different ways. The manner in which this is done may depend, in part, on whether the components are separated from the other components. In some embodiments some of the connections represented by the lead lines in the drawings may be in an integrated circuit, on a circuit board and/or over a backplane to other circuit boards.

The signals discussed herein may take several forms. For example, in some embodiments a signal may be an electrical signal transmitted over a wire while other signals may consist of light pulses transmitted over an optical fiber. A signal may comprise more than one signal. For example, a differential signal comprises two complementary signals or some other combination of signals. In addition, a group of signals may be collectively referred to herein as a signal.

Signals as discussed herein also may take the form of data. For example, in some embodiments an application program may send a signal to another application program. Such a signal may be stored in a data memory.

The components and functions described herein may be connected/coupled directly or indirectly. Thus, in some embodiments there may or may not be intervening devices (e.g., buffers) between connected/coupled components.

In summary, the invention described herein generally relates to an improved least mean square system and method. While certain exemplary embodiments have been described above in detail and shown in the accompanying drawings, it is to be understood that such embodiments are merely illustrative of and not restrictive of the broad invention. In particular, it should be recognized that the teachings of the invention apply to a wide variety of systems and processes. It will thus be recognized that various modifications may be made to the illustrated and other embodiments of the invention described above, without departing from the broad inventive scope thereof. In view of the above it will be understood that the invention is not limited to the particular embodiments or arrangements disclosed, but is rather intended to cover any changes, adaptations or modifications which are within the scope and spirit of the invention as defined by the appended claims.

1. An equalization coefficient generator comprising:
a demultiplexer configured to demultiplex a serial data signal to generate a plurality of demultiplexed data signals; and
a least mean square circuit configured to receive the demultiplexed data signals and an error signal to generate equalization coefficients.

2. The equalization coefficient generator of claim 1 comprising a clock generator configured to generate at least one clock signal for latching the demultiplexed data signals and a soft decision signal associated with the error signal.

3. The equalization coefficient generator of claim 2 wherein the clock generator comprises a delay lock loop.

4. The equalization coefficient generator of claim 2 comprising at least one flip flop for latching the demultiplexed data signals according to the at least one clock signal.

5. The equalization coefficient generator of claim 2 comprising at least one flip flop for delaying the at least one clock signal and at least one flip flop for latching the demultiplexed data signals according to the at least one delayed clock signal.

6. The equalization coefficient generator of claim 2 comprising at least one sample and hold circuit for latching a soft decision signal associated with the error signal according to the at least one clock signal.

7. The equalization coefficient generator of claim 1 comprising a delay lock loop for generating a clock signal having edges aligned with edges of a second clock signal and having edges aligned with a phase of a third clock signal.

8. The equalization coefficient generator of claim 7 wherein the delay lock loop detects a phase of the third clock with respect to an edge of the first clock signal and selectively adjusts the phase of the first clock signal in accordance with the detected phase.

9. The equalization coefficient generator of claim 7 wherein the delay lock loop comprises at least one flip flop for detecting the phase of the third clock with respect to an edge of the first clock signal.

10. The equalization coefficient generator of claim 9 wherein the delay lock loop comprises at least one divider configured to clock one of the at least one flip flop.

11. A method of generating equalization coefficients comprising:
demultiplexing a serial data signal to generate a plurality of demultiplexed data signals;
providing the demultiplexed data signals and an error signal to a least mean square process; and
generating equalization coefficient signals in accordance with the least mean square process.

12. The method of claim 11 comprising generating at least one clock signal for latching the demultiplexed data signals and a soft decision signal associated with the error signal.

13. The method of claim 12 comprising delaying the at least one clock signal and latching the demultiplexed data signals according to the at least one delayed clock signal.

14. The method of claim 12 comprising latching a soft decision signal associated with the error signal according to the at least one clock signal.

15. The method of claim 11 comprising generating a clock signal having edges aligned with edges of a second clock signal and having edges aligned with a phase of a third clock signal.

16. The method of claim 15 comprising detecting a phase of the third clock with respect to an edge of the first clock signal and selectively adjusting the phase of the first clock signal in accordance with the detected phase.

17. A decision feedback equalizer comprising:
a summer configured to add an input signal to at least one feedback signal scaled by at least one equalization coefficient to generate a soft decision signal;
a slicer configured to provide a binary signal from the soft decision signal; and
a retimer configured to sample the binary signal according to a clock signal;
a demultiplexer configured to demultiplex the sampled binary signal to generate a plurality of demultiplexed data signals; and
a least mean square circuit configured to receive the soft decision signal and the demultiplexed data signals to generate the at least one equalization coefficient.

18. The decision feedback equalizer of claim 17 comprising a clock generator configured to generate at least one clock signal for latching the demultiplexed data signals and the soft decision signal.

19. The decision feedback equalizer of claim 18 wherein the clock generator comprises a delay lock loop.

20. The decision feedback equalizer of claim 18 comprising at least one flip flop for latching the demultiplexed data signals according to the at least one clock signal.

21. The decision feedback equalizer of claim 18 comprising at least one flip flop for delaying the at least one clock signal and at least one flip flop for latching the demultiplexed data signals according to the at least one delayed clock signal.

22. The decision feedback equalizer of claim 18 comprising at least one sample and hold circuit for latching the soft decision signal according to the at least one clock signal.

23. The decision feedback equalizer of claim 17 comprising a delay lock loop for generating a clock signal having edges aligned with edges of a retimer clock signal and having edges aligned with a phase of a demultiplexer clock signal.

24. The decision feedback equalizer of claim 23 wherein the delay lock loop detects a phase of the demultiplexer clock with respect to an edge of the clock signal and selectively adjusts the phase of the clock signal in accordance with the detected phase.

25. A delay lock loop comprising:
a phase detector for detecting a difference in phase between a first signal and second signal and for generating a late/early signal;
a digital accumulator for filtering the late/early signal to generate a digital code signal;
a phase rotator for adjusting a phase of a reference clock signal in accordance with the digital code signal; and
a digital code adder for adjusting the digital code signal according to a phase relationship of the first signal and a third signal.

26. The delay lock loop of claim 25 wherein edges of the first clock signal are aligned with edges of the second clock signal and edges of the first clock signal are aligned with a phase of the third clock signal.

27. The delay lock loop of claim 25 wherein the delay lock loop detects a phase of the third clock signal with respect to an edge of the first clock signal and selectively adjusts the phase of the first clock signal in accordance with the detected phase.

28. The delay lock loop of claim 25 comprising at least one flip flop for detecting the phase of the third clock with respect to an edge of the first clock signal.

29. The delay lock loop of claim 28 comprising at least one divider configured to clock one of the at least one flip flop.

30. A method of sampling data to generate equalization coefficients comprising:
generating a first clock signal at a first clock frequency;
generating a second clock signal by dividing the first clock signal;
generating a third clock signal having edges aligned with edges of the first clock signal and having edges aligned with a phase of the second clock signal;
retiming a data signal using the first clock signal;
demultiplexing the retimed data signal using the second clock signal; and
sampling a first data signal and the demultiplexed data signal according to the third clock signal.
